(19) United States
(12) Patent Application Publication
(10) Pub. No.: US 2010/0006330 A1
(43) Pub. Date: Jan. 14, 2010

(54) STRUCTURE AND PROCESS OF EMBEDDED CHIP PACKAGE

(75) Inventors: Chieh-Chen Fu, Kaohsiung City (TW); Ying-Te Ou, Kaohsiung City (TW); Yung-Hui Wang, Kaohsiung City (TW)

Correspondence Address: J C PATENTS, 4 VENTURE, SUITE 250, IRVINE, CA, 92618, US

(73) Assignee: Advanced Semiconductor Engineering, Inc., Kaohsiung (TW)

(21) Appl. No.: 12/493,065

(22) Filed: Jun. 26, 2009

(30) Foreign Application Priority Data
Jul. 11, 2008 (TW) 97143131

(51) Int. Cl. H05K 1/16; H05K 13/00

(52) U.S. Cl. 174/260; 29/856; 174/263

(57) ABSTRACT

A process of an embedded chip package structure includes following steps. Firstly, a metal core layer having a first surface, a second surface opposite to the first surface, an opening, and a number of through holes are provided. The opening and the through holes connect the first surface and the second surface. A chip is then disposed in the opening. Next, a dielectric layer is formed in the opening and the through holes to fix the chip in the opening. Thereafter, a number of conductive vias are respectively formed in the through holes and insulated from the metal core layer by a portion of the dielectric layer located in the through holes. A circuit structure is then formed on the first surface of the metal core layer by performing a build-up process, and the circuit structure electrically connects the chip and the conductive vias.

### CROSS-REFERENCE TO RELATED APPLICATION

This application claims the priority benefit of Taiwan application serial no. 97143131, filed on Nov. 7, 2008. The entirety of the above-mentioned patent application is hereby incorporated by reference herein and made a part of specification.

### BACKGROUND OF THE INVENTION

1. Field of the Invention

The present invention relates to a chip package technology, and more particularly to an embedded chip package structure and a process of an embedded chip package.

2. Description of Related Art

A chip package aims at providing proper signal transmission paths and heat dissipation paths as well as protecting the chip structure. A leadframe serving as a carrier of a chip is frequently employed in a conventional wire bonding technique. As contact density in a chip gradually increases, the leadframe which is unable to satisfy current demands on the high contact density is replaced by a package substrate which can achieve favorable contact density. Besides, the chip is packaged onto the package substrate by conductive media, such as conductive wires or bumps.

In an individual package, there can be a single chip or multiple chips, such as multi-chip module (MCM) or system in a package (SIP). The multi-chip package is conducive to shortening signal transmission paths among the chips. Nonetheless, once one of the chips in the multi-chip package is damaged, it is unlikely to further use all of the other chips. Namely, manufacturing costs of the multi-chip package are subject to yield of the multi-chip package. As such, in some circuit designs, a plurality of single-chip packages that are stacked can also be one of the feasible solutions.

### SUMMARY OF THE INVENTION

The present invention is directed to a process of fabricating an embedded chip package structure.

The present invention is further directed to a chip package structure in which a chip is embedded in a substrate.

In the present invention, a process of an embedded chip package structure includes following steps. Firstly, a metal core layer having a first surface, a second surface opposite to the first surface, an opening, and a plurality of first through holes are provided. The opening and the first through holes penetrate the metal core layer. A chip is then disposed in the opening. Next, a dielectric layer is formed in the opening and the first through holes for fixing the chip in the opening. Thereafter, a plurality of conductive vias are respectively formed in the first through holes and insulated from the metal core layer by a portion of the dielectric layer located in the first through holes. A first circuit structure is then formed on the first surface of the metal core layer by performing a build-up process, and the first circuit structure electrically connects the chip and the conductive vias.

In the present invention, an embedded chip package structure including a metal core layer, a dielectric layer, a chip, a plurality of conductive vias, and a first circuit structure is further provided. The metal core layer has a first surface, a second surface opposite to the first surface, an opening, and a plurality of first through holes. The opening and the first through holes penetrate the metal core layer. The dielectric layer is disposed in the first through holes and the opening. The chip is embedded in a portion of the dielectric layer located in the opening. The conductive vias are respectively disposed in the first through holes and insulated from the metal core layer by a portion of the dielectric layer located in the first through holes. The first circuit structure is disposed on the first surface of the metal core layer and electrically connected to the chip and the conductive vias.

Based on the above, the process of the embedded chip package in the present invention can be applied for fabricating the embedded chip package structure. In addition, the chip of the embedded chip package structure is embedded in the substrate according to the present invention.

In order to make the above and other features and advantages of the present invention more comprehensible, an embodiment accompanied with figures is described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIGS. 1A through 1O are schematic cross-sectional views illustrating a process of an embedded chip package according to an embodiment of the present invention.

### DESCRIPTION OF EMBODIMENTS

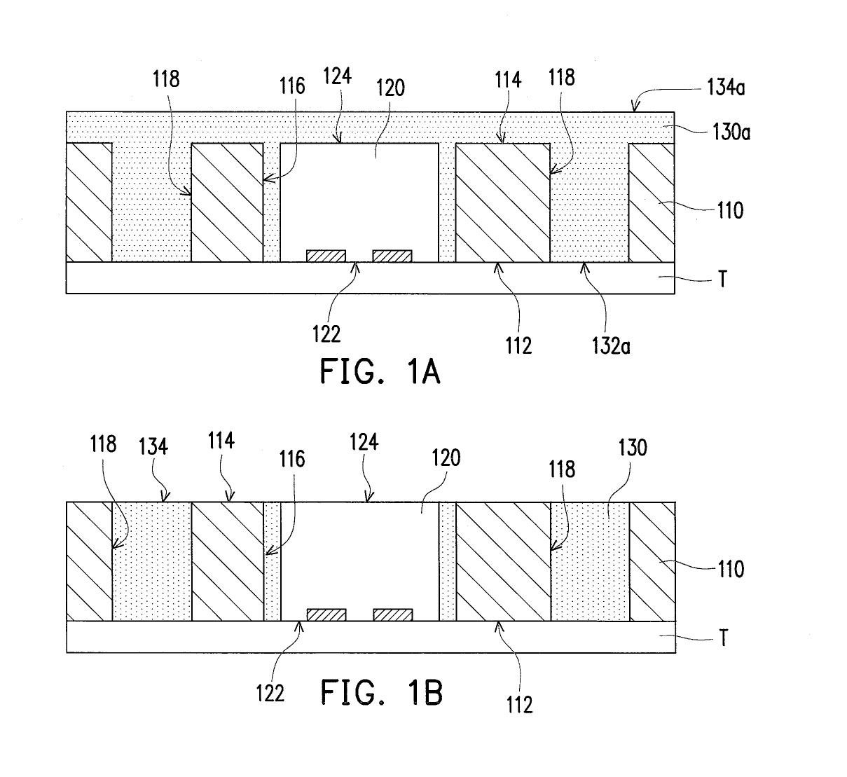

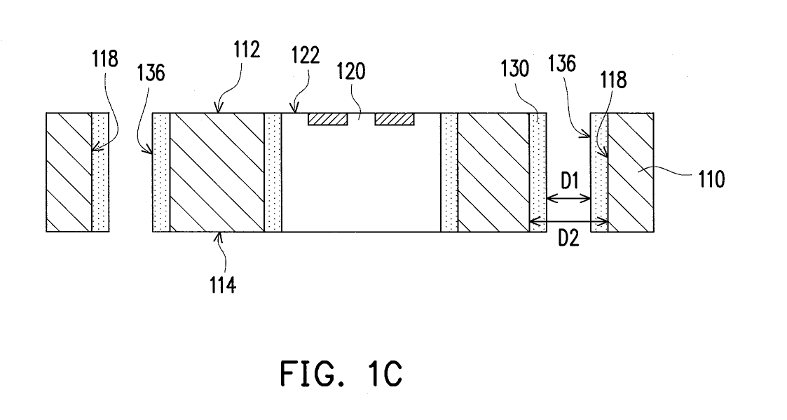

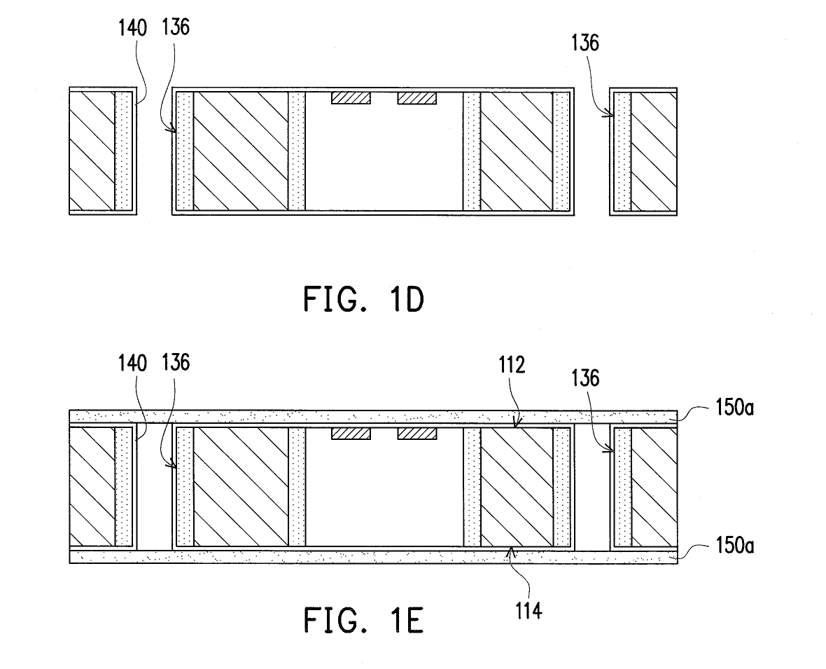

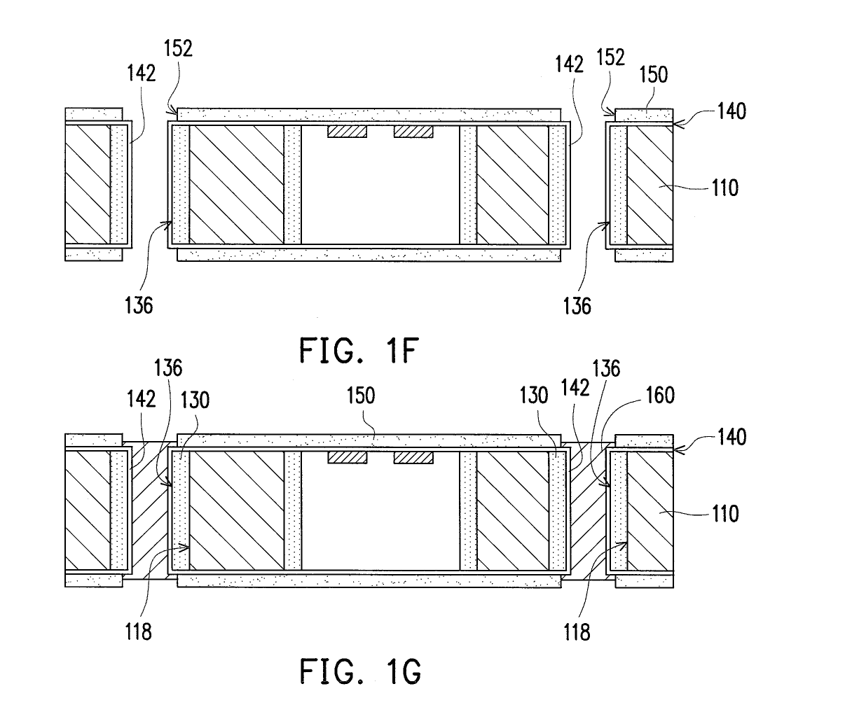

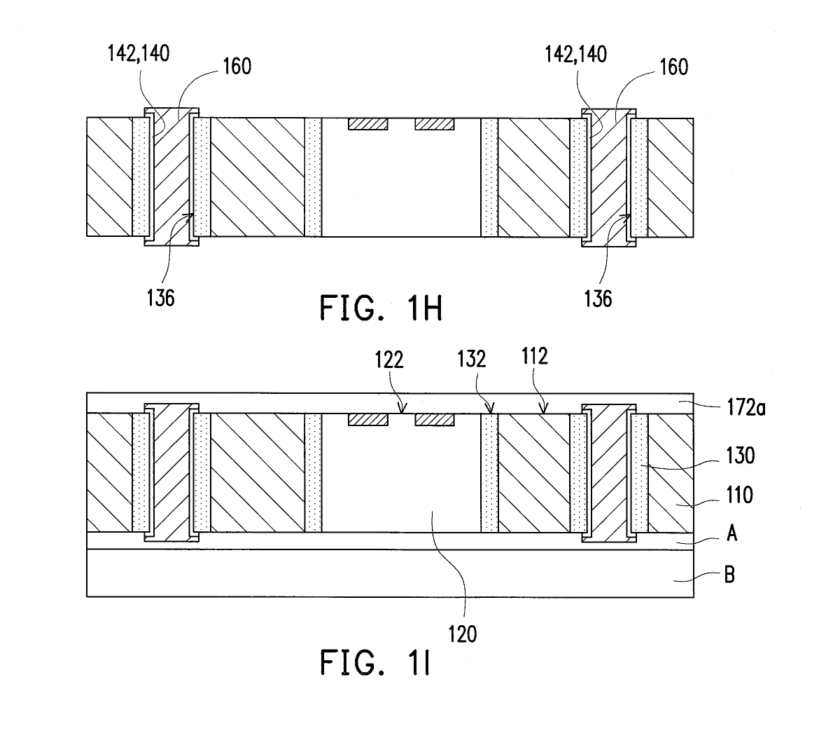

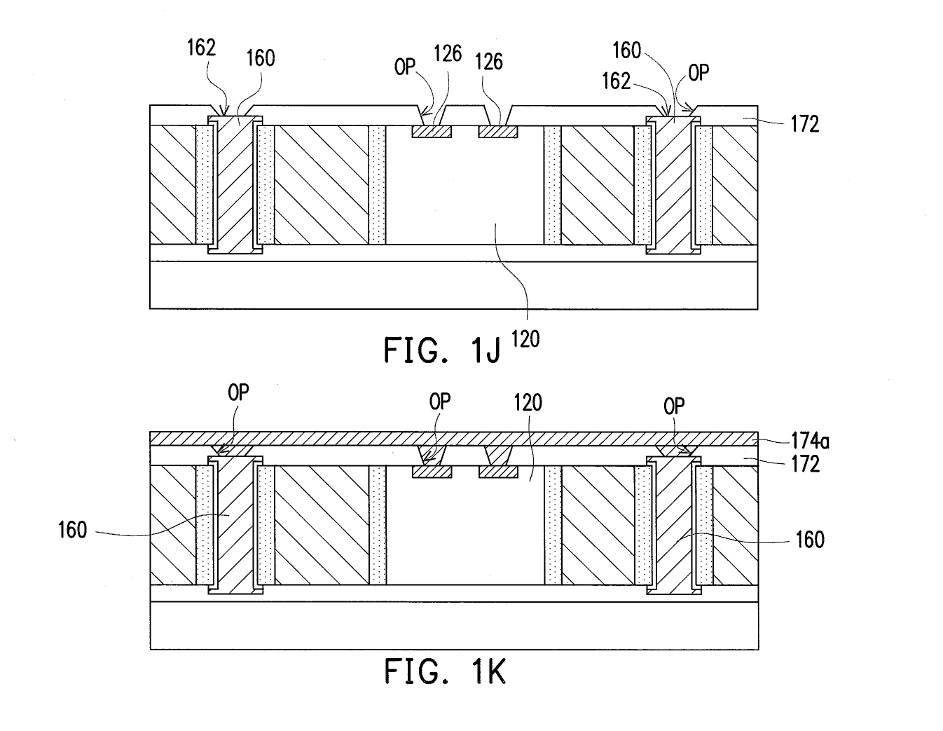

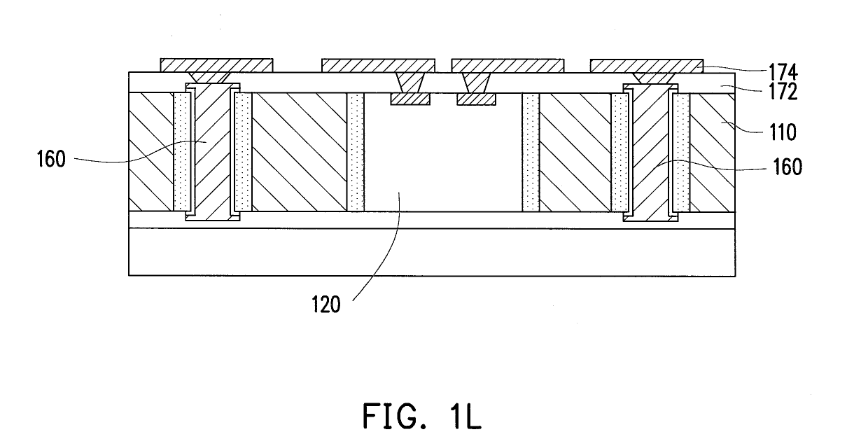

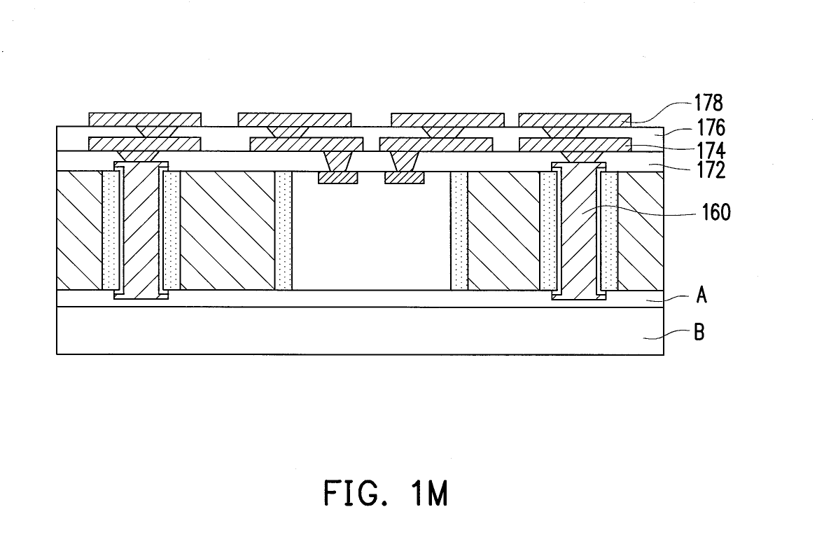

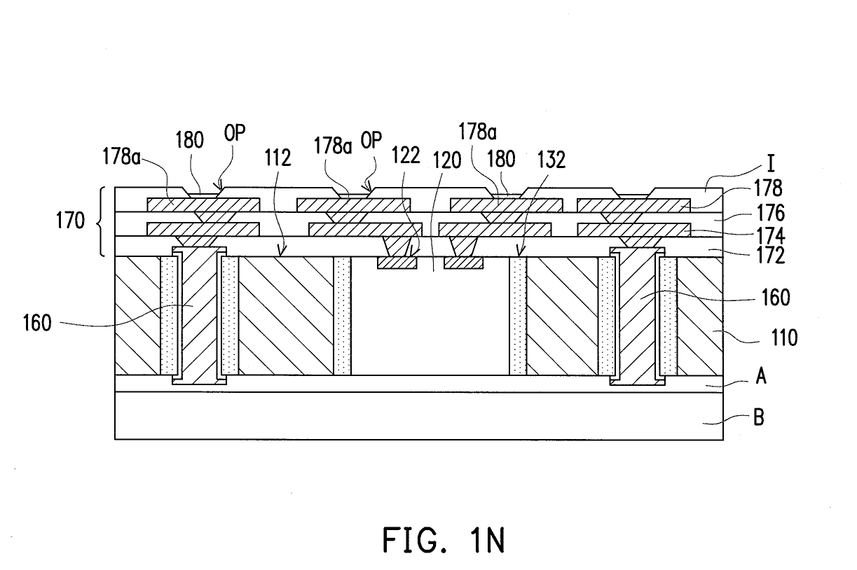

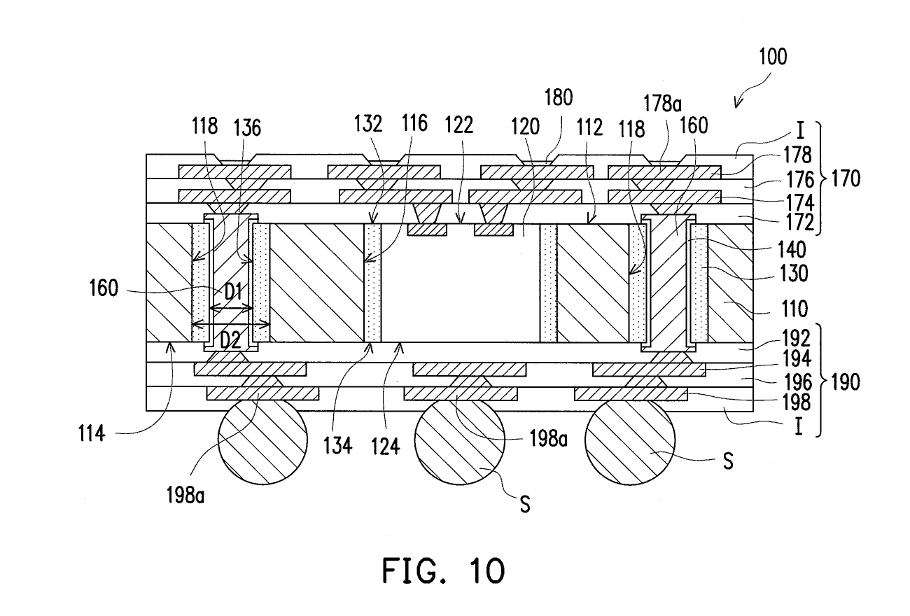

FIGS. 1A through 1O are schematic cross-sectional views illustrating a process of an embedded chip package according to an embodiment of the present invention.

Firstly, referring to FIG. 1A, a metal core layer 110 having a first surface 112, a second surface 114 opposite to the first surface 112, an opening 116, and a plurality of first through holes 118 are provided. The opening 116 and the first through holes 118 penetrate the metal core layer 110 and connect the first surface 112 and the second surface 114. As indicated in FIG. 1A, a thermal release material T is then adhered to the first surface 112 of the metal core layer 110. Besides, the thermal release material T covers the first through holes 118 and the opening 116.

Note that the metal core layer 110 is substantially shaped as a round plate (similar to a wafer shape) in the present embodiment. Hence, the process described in the present embodiment can be performed on the metal core layer 110 with use of semiconductor wafer-level manufacturing equipment. Thereby, a circuit structure (not shown) subsequently formed on the metal core layer 110 can have rather satisfactory yield. Additionally, circuit layers of the circuit structure can have relatively small line widths and pitches, and therefore circuit density is rather high. As such, the circuit structure of the present embodiment can have fewer circuit layers.

Next, a chip 120 is disposed in the opening 116 and fixed on the thermal release material T. In the present embodiment, the chip 120 can have an active surface 122 and a back surface 124 opposite to the active surface 122. Here, the active surface 122 faces the thermal release material T.

Thereafter, a dielectric layer 130a is formed in the opening 116 and the first through holes 118 to fix the chip 120 in the opening 116. According to the present embodiment, the chip 120, the dielectric layer 130a, and the metal core layer 110 are all disposed on the thermal release material T. Hence, the active surface 122 of the chip 120, a surface 132a of the dielectric layer 130a, and the first surface 112 of the metal core layer 110 are substantially aligned to one another.

After that, referring to FIG. 1A, in the present embodiment, a side 134a of the dielectric layer 130a away from the thermal release material T can be polished, so as to remove a portion of the dielectric layer 130a located outside the opening 116 and the first through holes 118 and to form a dielectric layer 130 merely located in the opening 116 and the first through holes 118 as depicted in FIG. 1B. Therefore, the back surface 124 of the chip 120, a surface 134 of the dielectric layer 130, and the second surface 114 of the metal core layer 110 can be substantially aligned to one another. Note that the active surface 122 of the chip 120 faces the thermal release material T in the present embodiment, and thereby the active surface 122 can be prevented from being damaged in the step of polishing the dielectric layer 130a.

Afterwards, referring to FIG. 1C, the thermal release material T is removed, and the metal core layer 110 is flipped over, such that the active surface 122 of the chip 120 faces up. Here, the thermal release material T is removed by heating the same, for example. A plurality of second through holes 136 are then respectively formed on a portion of the dielectric layer 130 located in the first through holes 118. Diameters D1 of the second through holes 136 are smaller than diameters D2 of the first through holes 118. Next, referring to FIG. 1D, a seed layer 140 is formed on inner walls of the second through holes 136.

Thereafter, referring to FIG. 1E, a plating-resistant layer 150a is formed to cover a portion of the seed layer 140 located on the first surface 112 and the second surface 114. Besides, in the present embodiment, the plating-resistant layer 150a further covers the second through holes 136. Afterwards, referring to FIG. 1F, the plating-resistant layer 150a is patterned to form a patterned plating-resistant layer 150. Here, a material of the plating-resistant layer 150a includes a photosensitive material, and a method of patterning the plating-resistant layer 150a includes performing an exposure and development process. The patterned plating-resistant layer 150 has a plurality of openings 152 respectively exposing the second through holes 136 and a portion of the seed layer 140 located in the second through holes 136.

Next, referring to FIG. 1G, a plurality of conductive vias 160 are respectively formed in the first through holes 118 and insulated from the metal core layer 110 by a portion of the dielectric layer 130 located in the first through holes 118. That is to say, the conductive vias 160 are electrically insulated from the metal core layer 110. Specifically, the conductive vias 160 are respectively electroplated on a portion 142 of the seed layer 140 located in the second through holes 136. Thereafter, referring to FIG. 1H, the patterned plating-resistant layer 150 and a portion of the seed layer 140 that is not covered by the conductive vias 160 are removed. Namely, only a portion of the seed layer 140 that is covered by the conductive vias 160 is left.

Afterwards, referring to FIG. 1I, the metal core layer 110 can be disposed on a carrier B, and an adhesion layer A can be interposed between the metal core layer 110 and the carrier B, so as to bond the metal core layer 110 to the carrier B. As shown in FIG. 1N, a first circuit structure 170 is then formed on the first surface 112 of the metal core layer 110 by performing a build-up process, and the first circuit structure 170 electrically connects the chip 120 and the conductive vias 160.

It should be noted that the active surface 122 of the chip 120, the surface 132 of the dielectric layer 130, and the first surface 112 of the metal core layer 110 are substantially aligned to one another according to the present embodiment. Therefore, yield of the first circuit structure 170 is rather high.

In particular, a method of forming the first circuit structure 170 is described as follows. First, referring to FIG. 1I, an insulating layer 172a is formed on the first surface 112 of the metal core layer 110. Next, as indicated in FIG. 1J, the insulating layer 172a is patterned for forming a patterned insulating layer 172 having a plurality of openings OP. The openings OP respectively expose a plurality of chip pads 126 of the chip 120 and an end 162 of each of the conductive vias 160.

Thereafter, referring to FIG. 1K, a conductive layer 174a is formed on the entire patterned insulating layer 172. The conductive layer 174a fills the openings OP to electrically connect the chip 120 and the conductive vias 160. As shown in FIG. 1L, the conductive layer 174a is then patterned for forming a circuit layer 174 electrically connected to the chip 120 and the conductive vias 160. Next, referring to FIG. 1M, a patterned insulating layer 176 and a circuit layer 178 are sequentially formed on the patterned insulating layer 172 by respectively performing the method of forming the patterned insulating layer 172 and the method of forming the circuit layer 174. The circuit layer 178 and the circuit layer 174 are electrically connected to each other.

Thereafter, referring to FIG. 1N, a patterned insulating layer I is formed on the patterned insulating layer 176. The patterned insulating layer I has a plurality of openings OP respectively exposing a plurality of pads 178a of the circuit layer 178. The pads 178a are suitable for being electrically connected to chip package structures (not shown) subsequently stacked on the metal core layer 110. According to the present embodiment, the patterned insulating layer 172, the circuit layer 174, the patterned insulating layer 176, the circuit layer 178, and the patterned insulating layer I together form the first circuit structure 170.

A surface finish 180 is then formed on each of the pads 178a, so as to prevent the pads 178a being oxidized or polluted by external substances. A material of the surface finish 180 is, for example, organic solderability preservatives (OSP), nickel\gold (Ni\Au), nickel\palladium\gold (Ni\Pd\Au), or stannum (Sn).

After that, referring to FIG. 1O, the carrier B and the adhesion layer A are removed. A second circuit structure 190 is then formed on the second surface 114 of the metal core layer 110 by performing a build-up process, and the second circuit structure 190 is electrically connected to the conductive vias 160. Besides, the second circuit structure 190 has a plurality of pads 198a.

It should be noted that the back surface 124 of the chip 120, the surface 134 of the dielectric layer 130, and the second surface 114 of the metal core layer 110 are substantially aligned to one another according to the present embodiment. Therefore, yield of the second circuit structure 190 is rather high.

Next, as shown in FIG. 1O, a plurality of solder balls S are respectively formed on the pads 198a and electrically connected to the second circuit structure 190.

The structure of the embedded chip package structure in the present embodiment is detailed hereinafter.

As illustrated in FIG. 1O, in the present embodiment, the embedded chip package structure 100 includes a metal core layer 110, a dielectric layer 130, a chip 120, a plurality of conductive vias 160, and a first circuit structure 170. The metal core layer 110 has a first surface 112, a second surface 114 opposite to the first surface 112, an opening 116, and a plurality of first through holes 118. The opening 116 and the first through holes 118 connect the first surface 112 and the second surface 114.

The dielectric layer 130 is disposed in the first through holes 118 and the opening 116, and the chip 120 is embedded in a portion of the dielectric layer 130 located in the opening 116. Note that the metal core layer 110 of the present embodiment is made of copper or other appropriate metal, for example. Therefore, heat conductivity of the metal core layer 110 is satisfactory. As such, heat energy generated by high speed operation of the chip 120 can be rapidly conducted by the metal core layer 110, so as to improve heat dissipating efficiency of the embedded chip package structure 100.

In the present embodiment, an active surface 122 and a back surface 124 of the chip 120 are exposed by the dielectric layer 130. The active surface 122 of the chip 120, a surface 132 of the dielectric layer 130, and the first surface 112 of the metal core layer 110 can be substantially aligned to one another. On the other hand, the back surface 124 of the chip 120 that is opposite to the active surface 122, a surface 134 of the dielectric layer 130, and the second surface 114 of the metal core layer 110 can be substantially aligned to one another.

The conductive vias 160 are respectively disposed in the first through holes 118 and insulated from the metal core layer 110 by a portion of the dielectric layer 130 located in the first through holes 118. That is to say, the conductive vias 160 are electrically insulated from the metal core layer 110. In the present embodiment, the embedded chip package structure 100 further includes a seed layer 140 located between the conductive vias 160 and the dielectric layer 130.

Specifically, the dielectric layer 130 has a plurality of second through holes 136 respectively positioned in the first through holes 118. Diameters D1 of the second through holes 136 are smaller than diameters D2 of the first through holes 118. The seed layer 140 is disposed on inner walls of the second through holes 136. The conductive vias 160 are respectively disposed in the second through holes 136 and located on the seed layer 140.

The first circuit structure 170 is disposed on the first surface 112 of the metal core layer 110 and electrically connected to the chip 120 and the conductive vias 160. The first circuit structure 170 can include a patterned insulating layer 172, a circuit layer 174, a patterned insulating layer 176, a circuit layer 178, and a patterned insulating layer I sequentially stacked on the first surface 112. Here, the circuit layer 174 and the circuit layer 178 are electrically connected to each other. Additionally, in the present embodiment, a surface finish 180 can be formed on each of the pads 178a of the first circuit structure 170.

Moreover, according to the present embodiment, a second circuit structure 190 can be disposed on the second surface 114 of the metal core layer 110. The second circuit structure 190 is electrically connected to the conductive vias 160. Besides, the second circuit structure 190 can include a patterned insulating layer 192, a circuit layer 194, a patterned insulating layer 196, a circuit layer 198, and a patterned insulating layer I sequentially stacked on the second surface 114. Here, the circuit layer 194 and the circuit layer 198 are electrically connected to each other.

The second circuit structure 190 can be electrically connected to external devices through a plurality of solder balls S disposed on the pads 198 of the second circuit structure 190. As such, the chip 120 can be electrically connected to an eternal device (e.g. a circuit board or another chip package structure) through the first circuit structure 170, the conductive vias 160, the second circuit structure 190, and the solder balls S.

In light of the foregoing, the process of the embedded chip package in the present invention can be applied for fabricating the embedded chip package structure. In some embodiments, the circuit density can be improved by utilizing the semiconductor wafer-level manufacturing equipment. In addition, the chip of the embedded chip package structure is embedded in the substrate according to the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A process of an embedded chip package, comprising:
providing a metal core layer having a first surface, a second surface opposite to the first surface, an opening, and a plurality of first through holes, wherein the opening and the plurality of first through holes penetrate the metal core layer;
disposing a chip in the opening;
forming a dielectric layer in the opening and the plurality of first through holes and fixing the chip in the opening;
respectively forming a plurality of conductive vias in the plurality of first through holes, the plurality of conductive vias being insulated from the metal core layer by a portion of the dielectric layer located in the plurality of first through holes; and
forming a first circuit structure on the first surface of the metal core layer by performing a build-up process, the first circuit structure electrically connecting the chip and the plurality of conductive vias.

2. The process of the embedded chip package as claimed in claim 1, further comprising:
forming a second circuit structure on the second surface of the metal core layer by performing a build-up process after forming the plurality of conductive vias, the second circuit structure electrically connecting the plurality of conductive vias.

3. The process of the embedded chip package as claimed in claim 2, further comprising:
forming a plurality of solder balls on the first circuit structure or the second circuit structure after forming the second circuit structure, the plurality of solder balls electrically connecting the first circuit structure or the second circuit structure.

4. The process of the embedded chip package as claimed in claim 1, further comprising:
forming a surface finish after forming the first circuit structure, the surface finish covering a pad of the first circuit structure.

5. The process of the embedded chip package as claimed in claim 1, further comprising:
polishing a portion of the dielectric layer located outside the opening and the plurality of first through holes after forming the dielectric layer, such that the dielectric layer is merely positioned in the opening and the plurality of first through holes.

6. The process of the embedded chip package as claimed in claim 1, further comprising:
respectively forming a plurality of second through holes on the portion of the dielectric layer located in the plurality of first through holes before forming the plurality of conductive vias, diameters of the plurality of second through holes being smaller than diameters of the plurality of first through holes;
forming a seed layer on inner walls of the plurality of second through holes; and
a portion of the seed layer located in the plurality of second through holes to form the plurality of conductive vias.

7. The process of the embedded chip package as claimed in claim 6, further comprising:
forming a patterned plating-resistant layer before forming the plurality of conductive vias, the patterned plating-resistant layer covering the portion of the seed layer located on the first surface and the second surface, a plurality of openings of the patterned plating-resistant layer respectively exposing the plurality of second through openings;
electroplating the plurality of conductive vias in the plurality of second through holes when forming the plurality of conductive vias; and
removing the patterned plating-resistant layer and a portion of the seed layer not covered by the plurality of the conductive vias after forming the plurality of the conductive vias.

8. The process of the embedded chip package as claimed in claim 1, further comprising:
adhering a thermal release material to the first surface of the metal core layer before disposing the chip in the opening, wherein the thermal release material covers the plurality of first through holes and the opening;
affixing the chip to the thermal release material when disposing the chip in the opening; and
removing the thermal release material after forming the dielectric layer.

9. The process of the embedded chip package as claimed in claim 8, wherein the chip has an active surface and a back surface opposite to the active surface, and the active surface faces the thermal release material.

10. The process of the embedded chip package as claimed in claim 9, wherein the active surface of the chip, a first surface of the dielectric layer, and the first surface of the metal core layer are substantially flush.

11. The process of the embedded chip package as claimed in claim 9, wherein the back surface of the chip, a second surface of the dielectric layer, and the second surface of the metal core layer are substantially flush.

12. An embedded chip package structure, comprising:
a metal core layer, having a first surface, a second surface opposite to the first surface, an opening, and a plurality of first through holes, wherein the opening and the plurality of first through holes penetrate the metal core layer,
a dielectric layer, disposed in the plurality of first through holes and the opening;
a chip, embedded in a portion of the dielectric layer located in the opening;
a plurality of conductive vias, respectively disposed in the plurality of first through holes and insulated from the metal core layer by a portion of the dielectric layer located in the plurality of first through holes; and
a first circuit structure, disposed on the first surface of the metal core layer and electrically connected to the chip and the plurality of conductive vias.

13. The embedded chip package structure as claimed in claim 12, further comprising:
a second circuit structure, disposed on the second surface of the metal core layer and electrically connected to the plurality of conductive vias.

14. The embedded chip package structure as claimed in claim 13, further comprising:
a plurality of solder balls, disposed on and electrically connected to the first circuit structure or the second circuit structure.

15. The embedded chip package structure as claimed in claim 12, further comprising:
a surface finish, covering a pad of the first circuit structure.

16. The embedded chip package structure as claimed in claim 12, wherein the dielectric layer exposes an active surface of the chip.

17. The embedded chip package structure as claimed in claim 16, wherein the active surface of the chip, a first surface of the dielectric layer, and the first surface of the metal core layer are substantially flush.

18. The embedded chip package structure as claimed in claim 12, wherein the dielectric layer exposes a back surface of the chip, and the back surface is opposite to an active surface of the chip.

19. The embedded chip package structure as claimed in claim 18, wherein the back surface of the chip, a second surface of the dielectric layer, and the second surface of the metal core layer are substantially flush.

20. The embedded chip package structure as claimed in claim 12, further comprising:
a seed layer, disposed between the plurality of conductive vias and the dielectric layer.
